(19) United States
(12) Patent Application Publication
(10) Pub. No.: US 2009/0146705 A1
(43) Pub. Date: Jun. 11, 2009

(54) DELAY LOCKED LOOP CIRCUIT AND METHOD FOR ELIMINATING JITTER AND OFFSET THEREIN

(76) Inventor: Chih-Haur Huang, Sinshih Township (TW)

Correspondence Address: HAYES SOLOWAY P.C., 3450 E. SUNRISE DRIVE, SUITE 140, TUCSON, AZ, 85718, US

(21) Appl. No.: 11/951,225

(22) Filed: Dec. 5, 2007

(51) Int. Cl. H03L 7/06

(52) U.S. Cl. 327/158

(57) ABSTRACT

A delay locked loop circuit (DLL) is provided. The delay locked loop circuit includes a shift register, a digital-to-analog converter and a voltage controlled delay line. The shift register outputs a digital signal in accordance with a phase difference between an input signal and a feedback signal. The digital-to-analog converter transfers the digital signal output from the shift register into a control voltage. The voltage controlled delay line outputs the feedback signal in accordance with the control voltage transferred by the digital-to-analog converter. A method for eliminating jitter and offset between an input signal and an output signal in a delay locked loop circuit is also disclosed.

### BACKGROUND

1. Field of Invention

The present invention relates to a clock synchronization circuit. More particularly, the present invention relates to a delay locked loop (DLL) circuit and a method for eliminating jitter and offset therein.

2. Description of Related Art

Clock synchronization circuits have been commonly used in electronic systems, so as to provide good clock distribution that is very important to overall performance of a product. Examples of such clock synchronization circuits include a phase locked loop (PLL) circuit and a delay locked loop (DLL) circuit. Conceptually, PLL and DLL circuits operate similarly. For DLL circuits, they include analog DLL circuits and digital DLL circuits, in which the analog DLL circuits have different performances from the digital DLL circuits.

FIG. 1 illustrates a typical analog DLL circuit. The analog DLL circuit 100 includes a phase-frequency detector (PFD) 102, a charge pump (CP) 104, a low pass filter (LPF) 106, a bias generator 108 and a voltage controlled delay line (VCDL) 110. The PFD 102 compares the phase difference between an input clock signal CKIN and a feedback clock signal CKON, and has two outputs UP and DN. The output of the PFD 102 is a pulse having a width equal to the amount by which CKIN leads or lags CKON. If CKIN leads CKON, the pulse appears on the UP output of the PFD 102. If CKIN lags CKON, the pulse appears on the DN output of the PFD 102.

The UP and DN outputs are input to the charge pump 104, and the charge pump 104 converts the input, either UP or DN, into an analog current for subsequent processing. The output current of the charge pump 104 is input to the LPF 106, and the LPF 106 functions to integrate the current output from the charge pump 104 to generate a control voltage VCTL. After that, the control voltage VCTL is input to the bias generator 108, and the bias generator 108 generates two outputs VBP and VBN according to the control voltage VCTL. Then, the VCDL 110 controls the frequency of the input clock signal CKIN based on the outputs VBP and VBN generated by the bias generator 108, so as to output N clock signals, i.e. CKO [1:N], that have different phases with each other, in which the output clock signal CKON is fed back to the PFD 102 to be compared.

The analog DLL circuit 100 has many advantages, one of which is the ability to achieve high resolutions. However, noise interference in the analog DLL circuit 100 significantly degrades the performance of the DLL circuit 100. The LPF 106 in the analog DLL circuit 100 also requires a large area for decreasing the noise interference. Thus, the production cost and the size cannot be reduced.

FIG. 2 illustrates a typical digital DLL circuit. The digital DLL circuit 200 includes a phase detector (PD) 202, a shift register 204 and a delay line 206. The phase detector 202 determines if a phase difference exists between an input clock signal CK and a feedback clock signal CKFB. The phase difference determines an appropriate shift in the input clock signal CK via adjustment of the shift register 204 to select a sufficient delay via the delay line 206, as is well understood by those skilled in the art.

The digital DLL circuit 200 has many advantages, one of which is the ability of tolerating noise. However, the digital DLL circuit 200 cannot be operated precisely. That is, the digital DLL circuit 200 fails to achieve high resolution like a typical analog DLL circuit. Thus, the digital DLL circuit 200 can only be used in electronic systems that do not need high resolutions.

### SUMMARY

In accordance with one embodiment of the present invention, a delay locked loop circuit (DLL) is provided. The delay locked loop circuit includes a shift register, a digital-to-analog converter and a voltage controlled delay line. The shift register outputs a digital signal in accordance with a phase difference between an input signal and a feedback signal. The digital-to-analog converter transfers the digital signal output from the shift register into a control voltage. The voltage controlled delay line outputs the feedback signal in accordance with the control voltage transferred by the digital-to-analog converter.

In accordance with another embodiment of the present invention, a delay locked loop circuit is provided. The delay locked loop circuit includes a phase difference detector, a shift register, a digital-to-analog converter, a bias generator and a voltage-controlled element. The phase difference detector detects a phase difference between an input signal and a feedback signal. The shift register is controlled by the phase difference detector and outputs a digital signal in accordance with the phase difference between the input signal and the feedback signal. The digital-to-analog converter transfers the digital signal output from the shift register into a control voltage. The bias generator couples to the digital-to-analog converter and generates at least one bias voltage in accordance with the control voltage. The voltage-controlled element is controlled by the bias voltage to output the feedback signal to the phase difference detector.

In accordance with yet another embodiment of the present invention, a method for eliminating jitter and offset between an input signal and an output signal in a delay locked loop circuit is provided. The method includes the steps of: determining a phase difference between the input signal and a feedback signal; generating a digital signal in accordance with the phase difference; converting the digital signal into an analog control voltage; generating a bias voltage corresponding to the analog control voltage; and delaying the input signal in accordance with the bias voltage to generate the output signal, in which the output signal has a phase substantially equal to the input signal.

For the foregoing embodiments of the present invention, the delay locked loop (DLL) circuit and the method for eliminating jitter and offset can be applied such that the DLL circuit has the ability to tolerate noise and achieve a high resolution. Furthermore, the charge pump and the low pass filter can be saved for the DLL circuit, so as to reduce the production cost and the size.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiments, with reference made to the accompanying drawings as follows:

FIG. 1 illustrates a typical analog DLL circuit;

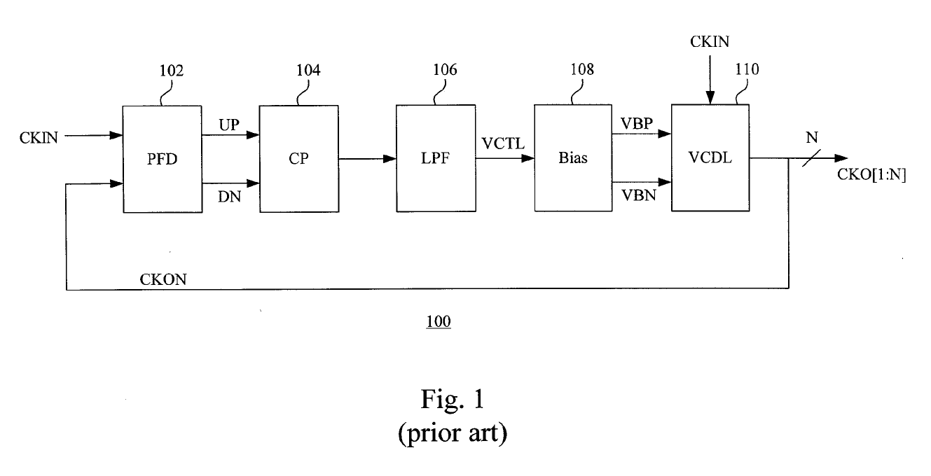

FIG. 2 illustrates a typical digital DLL circuit;

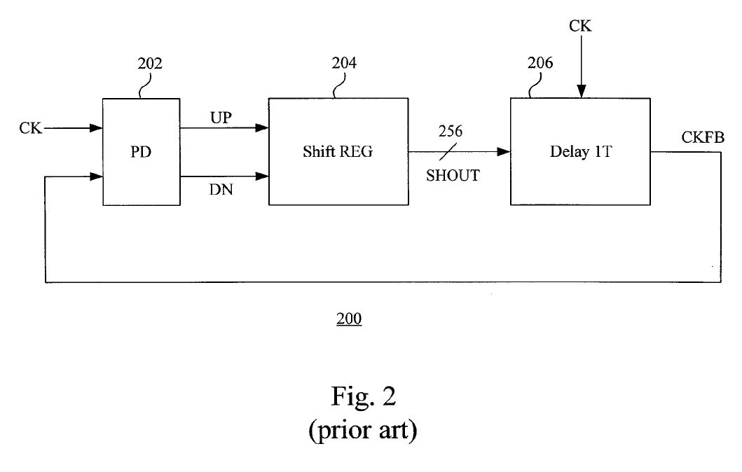

FIG. 3 illustrates a delay locked loop circuit according to one embodiment of the present invention;

FIG. 4 illustrates an R-string digital-to-analog converter according to one embodiment of the present invention; and

FIG. 5 illustrates a flow chart of the method for eliminating jitter and offset in a delay locked loop circuit according to one embodiment of the present invention.

### DESCRIPTION OF THE PREFERRED EMBODIMENTS

In the following detailed description, the embodiments of the present invention have been shown and described. As will be realized, the invention is capable of modification in various obvious respects, all without departing from the invention. Accordingly, the drawings and description are to be regarded as illustrative in nature, and not restrictive.

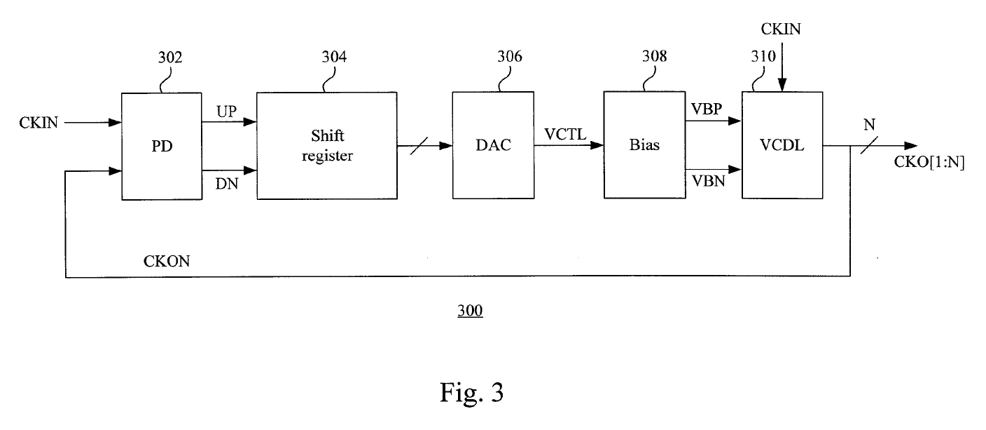

FIG. 3 illustrates a delay locked loop circuit according to one embodiment of the present invention. The delay locked loop (DLL) circuit 300 includes a phase difference detector (PD) 302, a shift register 304, a digital-to-analog converter (DAC) 306, a bias generator 308 and a voltage-controlled element. In the present embodiment, the voltage-controlled element is a voltage controlled delay line (VCDL) 310. The phase difference detector 302 detects a phase difference between an input clock signal CKIN and a feedback clock signal CKON, and has two outputs UP and DN. The output of the phase difference detector 302 is a pulse having a width equal to the amount by which CKIN leads or lags CKON. If CKIN leads CKON, the pulse appears on the UP output of the phase difference detector 302. If CKIN lags CKON, the pulse appears on the DN output of the phase difference detector 302.

The shift register 304 is controlled by the phase difference detector 302 and outputs a digital signal in accordance with the phase difference between the input clock signal CKIN and the feedback clock signal CKON. More particularly, the shift register 304 has register cells (not shown) inside, and the register cells shift signals according to the UP and DN output of the phase difference detector 302. Then, the shift register 304 outputs the corresponding digital signal based on the shift operation of the register cells.

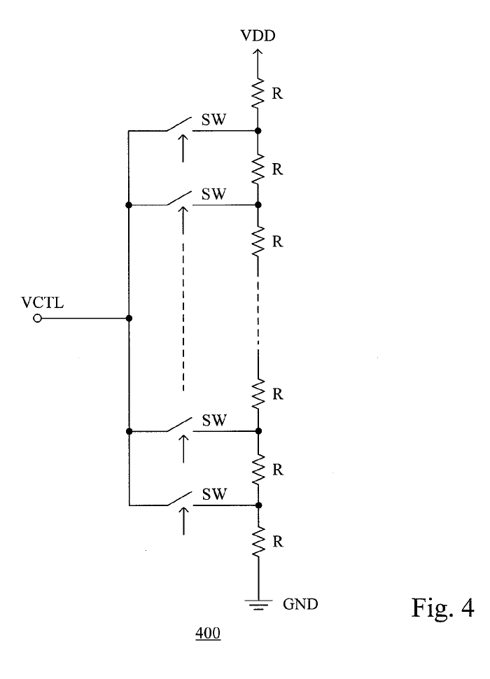

The digital-to-analog converter 306 transfers the digital signal output from the shift register 304 into a control voltage VCTL. In one embodiment, the digital-to-analog converter 306 is a resistor string (R-string) digital-to-analog converter. FIG. 4 illustrates an R-string digital-to-analog converter according to one embodiment of the present invention. The R-string digital-to-analog converter 400 includes resistors R and switches SW. The resistors R are serially connected, in which one end of the first resistor R is coupled to a constant voltage VDD and one end of the last resistor R is coupled to a ground voltage GND. Besides, one end of each corresponding switch SW is coupled between two connected resistors R, and the other end of each switch SW is connected with each other as the output, i.e. control voltage VCTL. When the R-string digital-to-analog converter 400 receives the digital signal output from the shift register 304, one of the switches SW is turned on according to the digital signal, such that the control voltage VCTL can be thus obtained.

Referring back to FIG. 3, the bias generator 308 is coupled to the digital-to-analog converter 306 and generates two bias voltages VBP and VBN in accordance with the control voltage VCTL. The voltage controlled delay line 310 is controlled by the bias voltages VBP and VBN and configured to delay the input clock signal CKIN to output N clock signals, i.e. CKO[1:N], in which the clock signal CKON is fed back to the phase difference detector 302. More particularly, the voltage controlled delay line 310 is configured to add a variable amount of delay to the input clock signal CKIN according to the bias voltages VBP and VBN. That is, the voltage controlled delay line 310 adds or subtracts sufficient delay, in accordance with the bias voltages VBP and VBN, to output different clock signals, i.e. CKO[1:N], with different phases and to make the phase of the output clock signal CKON match the phase of the input clock signal CKIN.

As a result, the former part (including PD 302 and shift register 304), which is related to digital design, of the DLL circuit 300 can be configured to solve the noise problem; that is, the DLL circuit 300 has the ability to tolerate the noise. Moreover, the latter part (including DAC 306, bias generator 308 and VCDL 310), which is related to analog design, of the DLL circuit 300 can be configured to solve the resolution problem; that is, the DLL circuit 300 has the ability to achieve a high resolution.

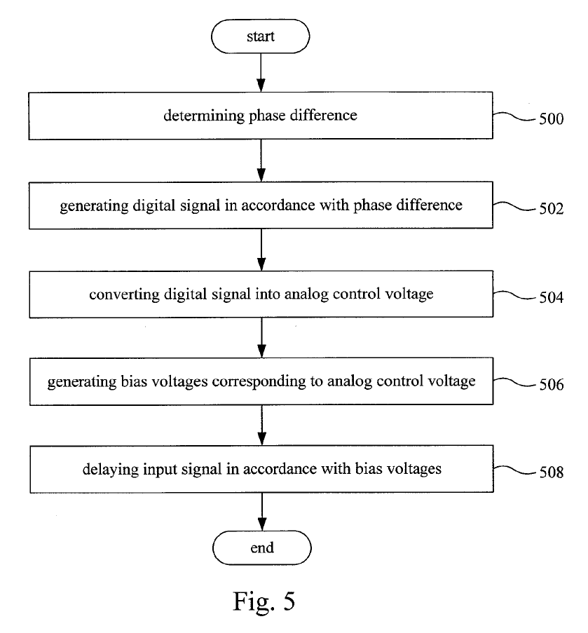

FIG. 5 illustrates a flow chart of the method for eliminating jitter and offset in a delay locked loop circuit according to one embodiment of the present invention. In the present embodiment, the method eliminates jitter and offset between an input clock signal and an output clock signal. Refer to FIG. 3 and FIG. 5. First, a phase difference between the input clock signal CKIN and the feedback clock signal CKON is determined (Step 500), in which Step 500 can be performed by the phase difference detector 302. Then, a digital signal is generated in accordance with the phase difference (Step 502), in which Step 502 can be carried out by the shift register 304.

After the digital signal is generated, the digital signal is converted into an analog control voltage VCTL (Step 504). Step 504 can be carried out by the digital-to-analog converter 306, and the digital-to-analog converter 306 can be a resistor string (R-string) digital-to-analog converter. Then, two bias voltages VBP and VBN corresponding to the analog control voltage VCTL are generated (Step 506), in which Step 506 can be performed by the bias generator 308. After that, the input clock signal CKIN is delayed in accordance with the bias voltages VBP and VBN to generate the output clock signals (Step 508), i.e. CKO[1:N], in which the output clock signal CKON is fed back to be compared with the input clock signal CKIN, and also has a phase substantially equal to the input clock signal CKIN when the DLL circuit 300 in the locked condition. Step 508 can be carried out by the voltage controlled delay line (VCDL) 310.

As a result, the method described above, which adopts the digital manner (including Step 500 and Step 502) and the analog manner (including Step 504, Step 506 and Step 508), can be applied to improve the DLL circuit, such that the DLL circuit is capable of tolerating noise and achieving a high resolution at the same time.

For the foregoing embodiments of the present invention, the delay locked loop (DLL) circuit and the method for eliminating jitter and offset can be applied such that the DLL circuit has the ability to tolerate the noise and achieve a high resolution. Furthermore, the charge pump and the low pass filter can be saved for the DLL circuit, so as to reduce the production cost and the size.

As is understood by a person skilled in the art, the foregoing embodiments of the present invention are illustrative of the present invention rather than limiting of the present invention. It is intended to cover various modifications and similar arrangements included within the spirit and scope of the appended claims, the scope of which should be accorded the broadest interpretation so as to encompass all such modifications and similar structures.

What is claimed is:

1. A delay locked loop circuit, comprising:
a shift register outputting a digital signal in accordance with a phase difference between an input signal and a feedback signal;
a digital-to-analog converter transferring the digital signal output from the shift register into a control voltage; and
a voltage controlled delay line outputting the feedback signal in accordance with the control voltage transferred by the digital-to-analog converter.

2. The delay locked loop circuit as claimed in claim 1, wherein the digital-to-analog converter is a resistor string (R-string) digital-to-analog converter.

3. The delay locked loop circuit as claimed in claim 1, wherein the voltage controlled delay line is configured for delaying the input signal to output the feedback signal.

4. A delay locked loop circuit, comprising:
a phase difference detector for detecting a phase difference between an input signal and a feedback signal;
a shift register controlled by the phase difference detector and outputting a digital signal in accordance with the phase difference between the input signal and the feedback signal;
a digital-to-analog converter transferring the digital signal output from the shift register into a control voltage;
a bias generator coupled to the digital-to-analog converter and generating at least one bias voltage in accordance with the control voltage; and
a voltage-controlled element controlled by the bias voltage to output the feedback signal to the phase difference detector.

5. The delay locked loop circuit as claimed in claim 4, wherein the digital-to-analog converter is a resistor string (R-string) digital-to-analog converter.

6. The delay locked loop circuit as claimed in claim 4, wherein the voltage-controlled element is a voltage controlled delay line.

7. The delay locked loop circuit as claimed in claim 6, wherein the voltage controlled delay line is configured for delaying the input signal to output the feedback signal to the phase difference detector.

8. A method for eliminating jitter and offset between an input signal and an output signal in a delay locked loop circuit, comprising the steps of:
determining a phase difference between the input signal and a feedback signal;
generating a digital signal in accordance with the phase difference;
converting the digital signal into an analog control voltage;
generating a bias voltage corresponding to the analog control voltage; and
delaying the input signal in accordance with the bias voltage to generate the output signal, wherein the output signal has a phase substantially equal to the input signal.

9. The method as claimed in claim 8, wherein the step of converting the digital signal into the analog control voltage is carried out by a digital-to-analog converter.

10. The method as claimed in claim 9, wherein the step of converting the digital signal into the analog control voltage is carried out by a resistor string (R-string) digital-to-analog converter.

11. The method as claimed in claim 8, wherein the step of generating the digital signal in accordance with the phase difference is carried out by a shift register.

12. The method as claimed in claim 8, wherein the step of delaying the input signal in accordance with the bias voltage to generate the output signal is carried out by a voltage controlled delay line.
